(19) United States
(12) Patent Application Publication
(10) Pub. No.: US 2024/0274404 A1
(43) Pub. Date: Aug. 15, 2024

(54) System and Method for Reducing Particle Formation in a Process Chamber of an Ion Implanter

(71) Applicant: Applied Materials, Inc., Santa Clara, CA (US)

(72) Inventors: Frank Sinclair, Hartland, ME (US); Tseh-Jen Hsieh, Rowley, MA (US); Vikram M. Bhosle, North Reading, MA (US); Bon-Woong Koo, Andover, MA (US); Gregory Edward Stratoti, Sandown, NH (US)

(21) Appl. No.: 18/107,819

(22) Filed: Feb. 9, 2023

(51) Int. Cl. H01J 37/304; C23C 14/22; C23C 14/54; H01J 37/09; H01J 37/317

(52) U.S. Cl. CPC H01J 37/304; C23C 14/221; C23C 14/54; H01J 37/09; H01J 37/3171; H01J 2237/006; H01J 2237/0453; H01J 2237/24564; H01J 2237/327

(57) ABSTRACT

An ion implanter and a method for reducing particle formation in a process chamber are disclosed. The ion implanter includes one or more gas sources in communication with the process chamber to introduce an oxygen-containing gas. After certain criteria has been met, a gas treatment process is initiated. This criteria may be related to the number of workpieces that have been processed or based on the number of particles detected in the process chamber. During the gas treatment process, the oxygen-containing gas is introduced and interacts with depositions disposed on the walls of the process chamber to transform the brittle film into a softer more pliable film that may be less susceptible to breaking. In some embodiments, the oxygen-containing gas may be oxygen gas, ozone or oxygen radicals which are introduced to the process chambers. In some embodiments, water vapor is introduced.

This disclosure describes systems and methods for reducing particle generation in the process chamber of an ion implanter.

### BACKGROUND

Semiconductor devices are fabricated using a plurality of processes, some of which implant ions into the workpiece. Certain implanters have the ability to monitor the ion beam that is being directed toward the workpiece. The incoming ion beam typically is very narrow in the height direction, but has a width that this greater than the diameter of the workpiece. This width may be achieved using a ribbon ion beam, or by the scanning of a spot ion beam.

To monitor this incoming ion beam, one or more current sensors, which may be Faraday cups or different sensors, may be located in the process chamber. These current sensors may be positioned such that when the platen is not in the operational position, the ion beam strikes the current sensors. The current sensors can then be used to measure the incoming beam current, as a function of position in the width direction. In some embodiments, there are a plurality of current sensor arranged in the width direction. In another embodiment, one current sensor is capable of moving in the width direction.

A structure, referred to as the dose cup assembly, is used to align and guide the ion beam toward the current sensors. Due to the position of the current sensors, the dose cup assembly that protects the current sensors is exposed in the ion beam. This exposure may cause a film to be formed on the dose cup assembly, which may interfere with the operation of the current sensors. This film may be brittle such that it is susceptible to cracking. Consequently, particles may form in the process chamber due to the cracking of this film. Particles may result in a higher rate of preventive maintenance (PM) routines that would lower the overall throughput of the ion implanter.

Therefore, it would be beneficial if there were a system and method of operating the ion implanter to reduce or minimize the formation of this brittle film.

### SUMMARY

A system and method for reducing particle formation in a process chamber is disclosed. The system includes one or more gas sources in communication with the process chamber to introduce gasses, such as oxygen-containing gasses. After certain criteria has been met, a gas treatment process is initiated. This criteria may be related to the number of workpieces that have been processed or based on the number of particles detected in the process chamber. During the gas treatment process, these oxygen-containing gasses are introduced and interact with depositions disposed on the walls of the process chamber to transform the brittle film into a softer more pliable film that may be less susceptible to breaking. In some embodiments, the oxygen-containing gas may be oxygen gas, ozone or oxygen radicals which are introduced to the process chambers. In some embodiments, water vapor is introduced.

According to one embodiment, an ion implanter is disclosed. The ion implanter comprises an ion source to generate an ion beam; a platen disposed within a process chamber, into which the ion beam is directed; a dose cup assembly disposed within the process chamber and aligned with an incoming ion beam; and a gas source in communication with the process chamber through a gas inlet to supply an oxygen-containing gas into the process chamber. In some embodiments, the ion implanter comprises a controller, wherein after a predetermined criteria is met, the controller enables the oxygen-containing gas to be introduced into the process chamber. In some embodiments, the gas inlet is affixed to a port of the process chamber. In some embodiments, the dose cup assembly comprises: a faceplate attached to a back wall of the process chamber of the ion implanter, the faceplate defining an opening;

an aperture plate defining a plurality of slots; and a tunnel having walls and sidewalls and having a proximal end and a distal end, located between the faceplate and the aperture plate, such that the proximal end is nearer to the faceplate and the distal end is nearer to the aperture plate; wherein the gas inlet is disposed in the tunnel so that the oxygen-containing gas is introduced directly into the dose cup assembly. In some embodiments, the gas source comprises a plasma generator. In certain embodiments, the ion implanter comprises a second gas source in communication with the process chamber, the second gas source supplying a NH₃—containing gas into the process chamber. In certain embodiments, the gas source comprises an ozone generator. In certain embodiments, the gas source comprises storage container containing an oxygen-containing gas. In certain embodiments, the ion implanter comprises a second gas source in communication with the process chamber, the second gas source supplying a hydrogen-containing gas into the process chamber.

According to another embodiment, a method of operating an ion implanter is disclosed. The method comprises generating an ion beam to be used to perform an ion implantation process on a number of workpieces located in a process chamber; and after a criteria is met, performing a gas treatment process, wherein an oxygen-containing species is introduced into the process chamber during the gas treatment process. In some embodiments, the gas treatment process comprises introducing oxygen gas into the process chamber.

In certain embodiments, the gas process further comprises introducing water vapor into the process chamber. In certain embodiments, the gas treatment process further comprises introducing hydrogen plasma into the process chamber. In certain embodiments, the gas treatment process further comprises changing a species of the ion beam to an inert species and directing the ion beam into the process chamber. In some embodiments, the gas treatment process comprises introducing ozone into the process chamber. In some embodiments, the gas treatment process comprises introducing oxygen radicals and ions into the process chamber. In certain embodiments, the gas treatment process further comprises introducing NH₃ gas into the process chamber. In certain embodiments, the gas treatment process further comprises introducing NH₃ plasma into the process chamber. In some embodiments, the gas treatment process comprises changing a feedgas used in an ion source to a species containing carbon monoxide or carbon dioxide so as to create an ion beam of oxygen ions and directing the oxygen ions into the process chamber. In some embodiments, the criteria is based on a number of workpieces processes since a previous gas treatment process or based on a number of particles detected on a workpiece or in the process chamber.

### BRIEF DESCRIPTION OF THE DRAWINGS

For a better understanding of the present disclosure, reference is made to the accompanying drawings, in which like elements are referenced with like numerals, and in which:

FIG. 1 is a block of an ion implantation system that uses the process chamber and a dose cup assembly;

FIG. 2A is a block diagram of a process chamber with a dose cup assembly and a current sensor according to one embodiment;

FIG. 2B is a block diagram of a process chamber with a dose cup assembly and a current sensor according to a second embodiment;

FIG. 3 shows the method of operating the ion implanter according to one embodiment; and

FIG. 4 shows various gas treatment processes.

### DETAILED DESCRIPTION

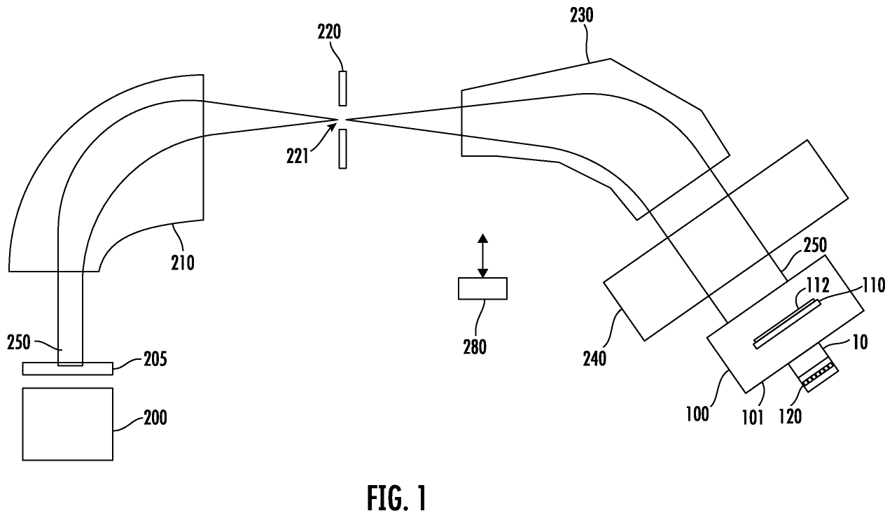

FIG. 1 shows an ion implanter that includes a process chamber 100 and a dose cup assembly 10. An ion source 200 is used to generate an ion beam 250. The ion source 200 may be a an indirectly heated cathode (IHC) ion source. Alternatively, the ion source 200 may be a capacitively coupled plasma source, an inductively coupled plasma source, a Bernas source or another source. Thus, the type of ion source is not limited by this disclosure. Disposed outside and proximate the extraction aperture of the ion source 200 is the extraction optics 205, which may comprise one or more electrodes.

Located downstream from the extraction optics 205 is a mass analyzer 210. The mass analyzer 210 uses magnetic fields to guide the path of the extracted ion beam. The magnetic fields affect the flight path of ions according to their mass and charge. A mass resolving device 220 that has a resolving aperture 221 is disposed at the output, or distal end, of the mass analyzer 210. By proper selection of the magnetic fields, only those ions in the ion beam 250 that have a selected mass and charge will be directed through the resolving aperture 221. Other ions will strike the mass resolving device 220 or a wall of the mass analyzer 210 and will not travel any further in the system.

A collimator 230 may disposed downstream from the mass resolving device 220. The collimator 230 accepts the ions from the ion beam 250 that pass through the resolving aperture 221 and creates an ion beam formed of a plurality of parallel or nearly parallel beamlets. The output, or distal end, of the mass analyzer 210 and the input, or proximal end, of the collimator 230 may be a fixed distance apart. The mass resolving device 220 is disposed in the space between these two components.

Located downstream from the collimator 230 may be an acceleration/deceleration stage 240. The acceleration/deceleration stage 240 is a beam-line lens component configured to independently control deflection, deceleration, and focus of the ion beam. For example, the acceleration/deceleration stage 240 may be an electrostatic filter (EF). The ion beam 250 that exits the acceleration/deceleration stage 240 enters the process chamber 100.

The process chamber 100 includes a platen 110, on which a workpiece 112 may be disposed. When in the operational position, the ion beam 250 impacts the workpiece 112. In addition, a dose cup assembly 10 is disposed at the back wall 101 of the process chamber 100. Located behind the dose cup assembly 10 may be one or more current sensors 120.

A controller 280 may be in communication with one or more of the power supplies such that the voltage or current supplied by these power supplies may be monitored and/or modified. The controller 280 may include a processing unit, such as a microcontroller, a computer, personal a special purpose controller, or another suitable processing unit. The controller 280 may also include a non-transitory storage element, such as a semiconductor memory, a magnetic memory, or another suitable memory. This non-transitory storage may element contain instructions and other data that allows the controller 280 to perform the functions described herein. The controller 280 may in communication with various components of the ion implanter to control the implantation process. Further, the controller 280 is in communication with the gas source 140 and the second gas source 148, if present.

In certain embodiments, the ion source 200 may generate a ribbon beam that travels through these components. Of course, other ion implanters may be utilized. For example, the ion implanter may generate a scanned ion beam rather than a ribbon ion beam. Such an ion implanter includes an ion source that creates a spot beam. This type of ion implanter also includes a mass analyzer and a mass resolving device, as described above. In addition, a scanner, which may be electrostatic or another type is used to create a scanned ion beam. The scanned ion beam may pass through an angle corrector. The angle corrector is designed to deflect ions in the scanned ion beam to produce an ion beam having parallel ion trajectories, thus focusing the scanned ion beam. Specifically, the angle corrector is used to alter the diverging ion trajectory paths into substantially parallel paths of the ion beam 250. In some embodiments, angle corrector may comprise magnetic pole pieces which are spaced apart to define a gap and a magnet coil which is coupled to a power supply. The scanned ion beam passes through the gap between the magnetic pole pieces and is deflected in accordance with the magnetic field in the gap. In other embodiments, the angle corrector may be an electrostatic lens sometimes referred to as a parallelizing lens.

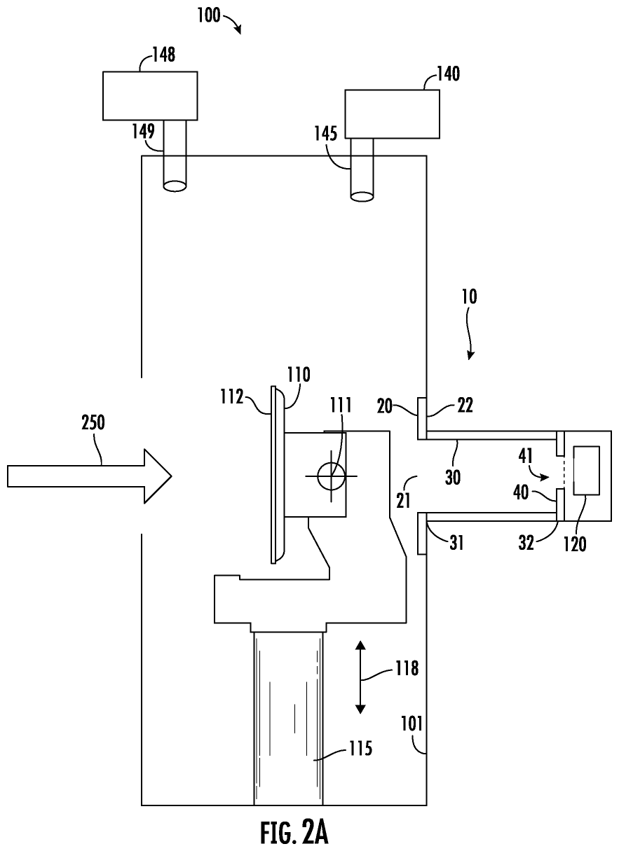

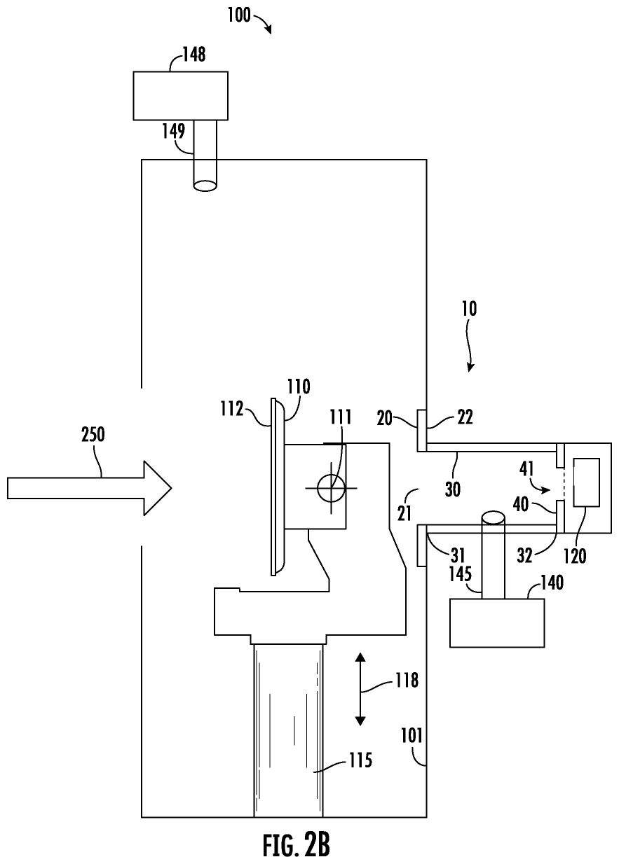

FIG. 2A shows one embodiment of the process chamber 100 of FIG. 1 in more detail. The process chamber 100 includes one or more current sensors 120. A dose cup assembly 10 is disposed between an incoming ion beam 250 and the current sensors 120. The dose cup assembly 10 comprises three components; a faceplate 20, a tunnel 30 and an aperture plate 40. As seen in FIG. 2A, the faceplate 20 is attached to the back wall of the process chamber 100 and covers the gap between the back wall and the tunnel 30. The faceplate 20 defines an opening 21 which allows ions to pass through to the current sensors 120.

The tunnel 30 extends backward from the faceplate 20. The term “backward” refers to the direction along the direction of the ion beam 250 and further away from the source of the ion beam 250. In some embodiments, the proximal end 31 of the tunnel 30 contacts the back surface 22 of the faceplate 20. In other embodiments, a gap may exist between the proximal end 31 of the tunnel 30 and the back surface 22 of the faceplate 20.

The aperture plate 40 is located near the distal end 32 of the tunnel 30 and is coupled to the tunnel 30. The aperture plate 40 comprises a plurality of slots 41 through which ions may pass. In some embodiments, the slots 41 may be between 2-6 inches in height and 1/16-¼ inches in width. In some embodiments, the aperture plate 40 contacts the distal end 32 of the tunnel 30. In other embodiments, a gap may exist between the aperture plate 40 and the distal end 32. In one embodiment, seven current sensors 120 are disposed behind seven respective slots 41. Of course, other numbers of slots and current sensors may be utilized. In another embodiment, one current sensor 120 is used, which translates along the width direction of the ion beam 250 to collect current from each slot 41.

Thus, the tunnel 30 is located between the faceplate 20 and the aperture plate 40, wherein the proximal end 31 of the tunnel 30 is closer to the back surface 22 of the faceplate 20 and the distal end 32 of the tunnel is closer to the aperture plate 40. In some embodiments, the proximal end 31 may be in contact with or attached to the back surface 22 of the faceplate. In some embodiments, the distal end 32 may be in contact with portions of the aperture plate 40. In some embodiments, the tunnel 30 is attached to the aperture plate 40 using brackets.

A platen 110 is also disposed in the process chamber 100. The platen 110 may be an electrostatic platen that is used to clamp and hold the workpiece while the ion beam 250 is directed into the process chamber 100. In some embodiments, the platen 110 may be elevated and lowered in the Y direction 118 through the movement of shaft 115. Additionally, the platen 110 may rotate about X axis 111. In certain embodiments, the platen 110 may be rotated 90° so that the clamping surface of the platen is horizontal, allowing a workpiece 112 to be placed on the platen 110. The platen 110 is then rotated into the operational, or implant position, which is shown in FIG. 2A.

To monitor the ion beam 250, the platen 110 is lowered by actuation of shaft 115 in the Y direction 118. This movement removes the platen 110 from the path of the ion beam 250. Thus, the ion beam 250 is unobstructed as it travels toward the current sensors 120. During prolonged operation, the ion beam 250 may cause a film to be created in the dose cup assembly 10. For example, extended implantation of boron ions may result in a boron carbide film in the dose cup assembly 10. To mitigate this, a gas source 140 is employed.

In the embodiment shown in FIG. 2A, a gas source 140 is in communication with the process chamber 100 through a gas inlet 145. The gas inlet 145 may be disposed on a top wall of the process chamber 100, although other locations are also possible. In some embodiments, the process chamber 100 may be equipped with one or more ports. The gas inlet 145 may be in communication with one of these pre-existing ports.

The gas source 140 may be a source of molecular oxygen (02). In certain embodiments, the gas source 140 contains oxygen. In another embodiment, the gas source 140 is an ozone generator such that 03 is introduced into the process chamber 100. In another embodiment, the gas source 140 is a plasma source that is used to create oxygen radicals and oxygen ions, such that oxygen radicals and ions are introduced into the process chamber 100. In certain embodiments, the controller 280 is used to enable the flow of the gas into the process chamber 100. This may be achieved using a mass flow controller or other valve. Additionally, in the embodiment where ozone is generated, the controller 280 may be configured to enable and disable the ozone generator. Further, in the embodiment where oxygen radicals are generated, the controller 280 may be configured to enable and disable the operation of the plasma generator.

In some embodiments, a second gas source 148 may be utilized. The second gas source 148 may be in communication with the process chamber via a gas inlet 149. The second gas source 148 may be a storage container used to hold a gas or may be a plasma generator.

FIG. 2B shows another embodiment of the process chamber 100. In this embodiment, the gas inlet 145 is disposed in the tunnel 30 so that the oxygen, ozone or oxygen radicals are introduced directly into the dose cup assembly 10. In some embodiments, the gas inlet 145 is located near the proximal end 31 of the tunnel 30, such as within 2 inches of the faceplate 20. In other embodiments, the gas inlet 145 is located near the distal end 32 of the tunnel, such as within 2 inches of the aperture plate 40. The remaining components of the process chamber 100 are as described with respect to FIG. 2A.

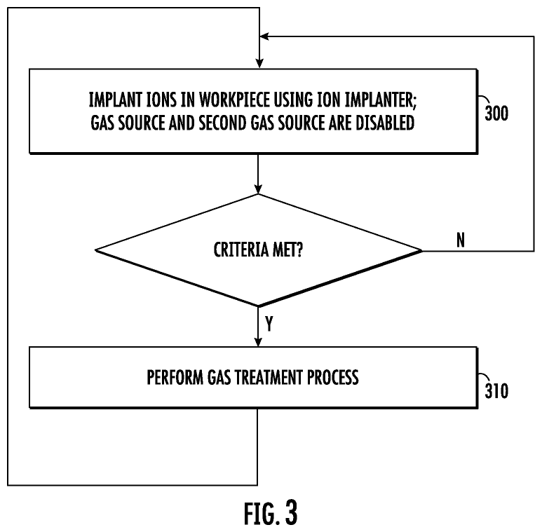

Having described the ion implanter and the process chamber, methods of operating the implanter using the controller 280 will now be described. This sequence is also shown in FIG. 3. During normal operation, as shown in Box 300, the controller 280 enables the ion source 200 to generate ions that are accelerated toward the process chamber 100. The ions that are produced by the ion source 200 may be boron ions, although the species of ion is not limited by this disclosure. At this time, the gas source 140 and the second gas source 148 (if present) are disabled such that no additional gas or radicals are introduced to the process chamber 100 at this time. As shown in Box 310, after a certain criteria is met, the ion implanter is subject to a gas treatment process. This criteria may be based on the number of workpieces that have been processed since the last gas treatment process. For example, a predetermined number of workpieces may be implanted and afterward, the gas treatment process is initiated. Alternatively, this criteria may be based on the number or percentage of certain particles detected on the workpiece or within the process chamber. This may be detected using several techniques that are known in the art. The gas treatment process serves to reduce or eliminate the brittle film that forms during the ion implantation process. After the gas treatment process is completed, the ion implanter returns to normal operation. The gas treatment process may be terminated based on a predetermined amount of time. Alternatively, the gas treatment process may be terminated based on the number or percentage of certain particles detected on the workpiece or within the process chamber.

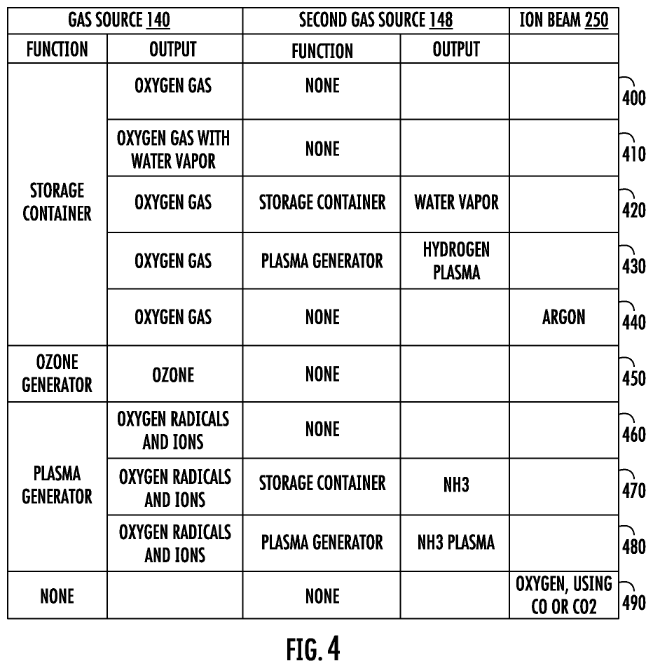

Unlike conventional cleaning processes, vacuum is not broken in this gas treatment process. FIG. 4 shows the various gas treatment processes that may be performed. In all embodiments, an oxygen-containing species is introduced into the process chamber 100.

In the embodiments shown in Boxes 400-440, the gas source 140 may be a storage container, holding molecular oxygen gas, either alone or in combination with another gas.

In one embodiment, shown in Box 400, the gas source 140 supplies pure oxygen gas to the process chamber 100. This may be accomplished using a mass flow controller that is controlled by the controller 280.

In another embodiment, shown in Box 410, the oxygen gas may be accompanied by water vapor. This may be accomplished by storing the water vapor in the same gas source 140 as the oxygen gas. Alternatively, this may be accomplished by storing the water vapor in the second gas source 148, which may be a storage container, as shown in Box 420.

In another embodiment, shown in Box 430, the second gas source 148 may be a plasma generator. In this embodiment, the oxygen may be introduced from the gas source 140 while hydrogen plasma is introduced from the second gas source 148. In some embodiments, the hydrogen plasma may be introduced before the oxygen gas.

In another embodiment, shown in Box 440, an ion beam, comprising an inert species, such as argon, is used in conjunction with the oxygen gas from the gas source 140. In this embodiment, the controller 280 enables the ion source 200 to generate ions using an inert gas. This ion beam is then directed to the process chamber 100. The energy of the ion beam assists in the cleaning process.

In the embodiment shown in Box 450, the gas source 140 is an ozone generator. The ozone generator is used to introduced ozone into the process chamber. Although not shown in FIG. 4, the second gas sources 148 shown in Boxes 420-430 may also apply to the use of ozone.

In the embodiments shown in Boxes 460-480, the gas source 140 may be a plasma generator, generating oxygen radicals and ions. In the embodiment shown in Box 460, the second gas source 148 is not used, and oxygen radicals and ions are introduced by the gas source 140.

In the embodiment shown in Box 470, the second gas source 148 may be a storage container, used to supply NH₃ gas to the process chamber 100. The combination of oxygen radicals and NH₃ leads to the creation of water.

In the embodiment shown in Box 480, the second gas source 148 may be a plasma generator, used to supply NH₃ plasma to the process chamber 100.

In the embodiment shown in Box 490, the gas source 140 and the second gas source 148 are not used. Rather, the controller 280 configured the ion implanter to produce an ion beam 250 comprising oxygen ions. This may be achieved by using CO or CO₂ as the feedgas in the ion source.

The present system and method have many advantages. In certain current configurations, the species of the ion beam may interact with the material used to form the components that make up the dose cup assembly. For example, boron ions may interact with graphite components to form a film of boron carbide. This film is brittle and may crack, forming particles. By performing a gas treatment process, which introduces oxygen into the process chamber 100, the boron carbide film may be transformed.

Specifically, the introduction of oxygen may transform the boron carbide film into a boron oxide film. It is known that when boron depositions are exposed to oxygen or moisture, these depositions may be transformed into boron oxide films, which are much softer, and therefore less likely to crack and create particles.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An ion implanter, comprising:
an ion source to generate an ion beam;
a platen disposed within a process chamber, into which the ion beam is directed;
a dose cup assembly disposed within the process chamber and aligned with an incoming ion beam; and
a gas source in communication with the process chamber through a gas inlet to supply an oxygen-containing gas into the process chamber.

2. The ion implanter of claim 1, further comprising a controller, wherein after a predetermined criteria is met, the controller enables the oxygen-containing gas to be introduced into the process chamber.

3. The ion implanter of claim 1, wherein the gas inlet is affixed to a port of the process chamber.

4. The ion implanter of claim 1, wherein the dose cup assembly comprises:
a faceplate attached to a back wall of the process chamber of the ion implanter, the faceplate defining an opening;
an aperture plate defining a plurality of slots; and
a tunnel having walls and sidewalls and having a proximal end and a distal end, located between the faceplate and the aperture plate, such that the proximal end is nearer to the faceplate and the distal end is nearer to the aperture plate;
wherein the gas inlet is disposed in the tunnel so that the oxygen-containing gas is introduced directly into the dose cup assembly.

5. The ion implanter of claim 1, wherein the gas source comprises a plasma generator.

6. The ion implanter of claim 5, further comprising a second gas source in communication with the process chamber, the second gas source supplying a NH₃—containing gas into the process chamber.

7. The ion implanter of claim 1, wherein the gas source comprises an ozone generator.

8. The ion implanter of claim 1, wherein
the gas source comprises a storage container containing the oxygen-containing gas.

9. The ion implanter of claim 8, further comprising a second gas source in communication with the process chamber, the second gas source supplying a hydrogen-containing gas into the process chamber.

10. A method of operating an ion implanter, comprising:
generating an ion beam to be used to perform an ion implantation process on a number of workpieces located in a process chamber; and
after a criteria is met, performing a gas treatment process, wherein an oxygen-containing species is introduced into the process chamber during the gas treatment process.

11. The method of claim 10, wherein the gas treatment process comprises introducing oxygen gas into the process chamber.

12. The method of claim 11, wherein the gas treatment process further comprises introducing water vapor into the process chamber.

13. The method of claim 11, wherein the gas treatment process further comprises introducing hydrogen plasma into the process chamber.

14. The method of claim 11, wherein the gas treatment process further comprises changing a species of the ion beam to an inert species and directing the ion beam into the process chamber.

15. The method of claim 10, wherein the gas treatment process comprises introducing ozone into the process chamber.

16. The method of claim 10, wherein the gas treatment process comprises introducing oxygen radicals and ions into the process chamber.

17. The method of claim 16, wherein the gas treatment process further comprises introducing NH₃ gas into the process chamber.

18. The method of claim 16, wherein the gas treatment process further comprises introducing NH₃ plasma into the process chamber.

19. The method of claim 10, wherein the gas treatment process comprises changing a feedgas used in an ion source to a species containing carbon monoxide or carbon dioxide so as to create an ion beam of oxygen ions and directing the oxygen ions into the process chamber.

20. The method of claim 10, wherein the criteria is based on a number of workpieces processes since a previous gas treatment process or based on a number of particles detected on a workpiece or in the process chamber.
